(19) United States
(12) Patent Application Publication
(10) Pub. No.: US 2008/0002363 A1
(43) Pub. Date: Jan. 3, 2008

(54) DIRECT LIQUID JET IMPINGEMENT MODULE FOR HIGH HEAT FLUX ELECTRONICS PACKAGES

(75) Inventors: Levi A. Campbell, Poughkeepsie, NY (US); Rehan Choudhary, Poughkeepsie, NY (US); Michael J. Ellsworth JR., Lagrangeville, NY (US); Kenneth C. Marston, Poughquag, NY (US); Hilton T. Toy, Wappingers Falls, NY (US)

Correspondence Address: INTERNATIONAL BUSINESS MACHINES CORPORATION, IPLAW DEPARTMENT, 2455 SOUTH ROAD - MS P386, POUGHKEEPSIE, NY, 12601, US

(73) Assignee: International Business Machines Corporation, Armonk, NY (US)

(21) Appl. No.: 11/427,380

(22) Filed: Jun. 29, 2006

(51) Int. Cl. H05K 7/20

(52) U.S. Cl. 361/699

(57) ABSTRACT

A direct liquid jet impingement module and associated method of providing such used in cooling of electronic components housed in an electronic package is provided. The module comprises a frame having an orifice to be placed over to-be-cooled components. A manifold is then disposed over the frame, such that the manifold opening is aligned with the frame orifice to ultimately enable fluid impingement on the to-be-cooled components. The manifold is formed to receive an inlet for the flow of coolants and an outlet fitting for removal of dissipated heat. A jet orifice plate is also provided inside the manifold opening, aligned with the frame orifice for directing fluid coolant flow over to-be-cooled components.

### CROSS-REFERENCE TO RELATED APPLICATIONS

This application contains subject matter which is related to the subject matter of the following co-pending application, which is also assigned to the same assignee as this application, International Business Machines Corporation of Armonk, N.Y. The following application is hereby incorporated herein by reference in its entirety: Ser. No. 10/904,555 filed on Nov. 16, 2004, entitled “Fluidic Cooling Systems and Methods for Electronic Components” and assigned to the same assignee as this application.

### BACKGROUND OF THE INVENTION

1. Field of the Invention

This invention relates to cooling of electronic packages in general and more particularly to cooling of electronic packages in a computing environment.

2. Description of Background

The industry trend has been to continuously increase the number of electronic components inside computing system environments. Compactness allows for selective fabrication of smaller and lighter devices that are more attractive to the consumer. In addition, compactness also allows many of the circuits to operate at higher frequencies and at higher speeds due to shorter electrical distances in these devices. Despite many of the advantages associated with this industry goal, providing many such components in a small footprint create device performance challenges. One such challenge has to do with thermal management of the overall environment. Heat dissipation, if unresolved, can result in electronic and mechanical failures that will affect overall system performance, no matter what the size of the environment.

In many computing environments, especially those that incorporate microprocessors and other such components, the microprocessors inside the environment increase in performance, the active circuitry of a chip is driven to smaller devices and higher power consumption. Higher power consumption and smaller devices lead to high heat loads and high heat fluxes. Reliability limitations dictate that the temperature of the devices may not exceed a known maximum value.

The prior art has struggled with designing high-performance cooling solutions that can dissipate this heat. Current cooling solutions depend on conduction cooling through one or more thermal interfaces to an air-cooled heat sink, possibly employing a spreader or vapor chamber. To further increase the heat dissipation capability of air-cooled systems, greater airflow must be used. Unfortunately, providing greater airflow is not always possible. Many limitations exist that must be taken into consideration, among which are both noise (acoustic) considerations as well as power concerns.

An alternative to air cooling is liquid or fluid cooling methods that have been recently incorporated into some designs. Liquid cooling, however, is also limited by several factors. Liquid cooled microprocessors in the prior art are either immersion cooled in a dielectric fluid and cooled by pool boiling or by incorporating cold plate designs. Immersion cooled modules have the limitation that the critical heat flux of the dielectric refrigerants is relatively low, limiting the chip heat flux. Cold plate cooled modules have the limitation that a thermal interface material must be used, limiting the heat transfer capabilities of the module. Consequently, new high performance cooling solutions must be developed that can overcome the prior art limitations enumerated above.

### SUMMARY OF THE INVENTION

The shortcomings of the prior art are overcome and additional advantages are provided through a direct liquid jet impingement module and associated method of providing such used in cooling of electronic components housed in an electronic package. The module comprises a frame having an orifice to be placed over to-be-cooled components. A manifold having an insert is then disposed over the frame, such that the manifold opening is aligned with the frame opening to ultimately enable fluid impingement on the to-be-cooled components. The manifold is formed to receive an inlet for the flow of coolant and an outlet fitting for removal of heated fluid. A jet orifice plate is also provided inside the manifold opening, aligned with the frame orifice for directing fluid coolant flow over to-be-cooled components.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is an isometric illustration of a direct liquid jet impingement module as per one embodiment of the present invention;

FIG. 2 is an exploded view of the direct liquid jet impingement module of the embodiment illustrated in FIG. 1;

FIGS. 3a through 3c are different views of the direct liquid jet impingement module of the embodiment illustrated in FIG. 1;

FIG. 4 is a detailed illustration of the molded manifold with orifice plate used in the direct liquid jet impingement module of the embodiment illustrated in FIG. 1; and

FIGS. 5a through 5c provide for different views of the orifice plate molded into the manifold as provided by the embodiment of FIG. 4.

### DESCRIPTION OF THE INVENTION

The present invention provides for a direct liquid jet impingement module that eliminates the need for a thermal interface material. As will be discussed in detail below, the direct liquid jet impingement module of the present invention is capable of utilizing a variety of coolants, including but not limited to water based coolants which take advantage of superior thermal properties in contrast to dielectric liquids. This is partly due to the unique sealing structures used in this invention, and introduced in previously filed application FIS9-2004-0185 (Ser. No. 10/904,555 filed Nov. 16, 2004), which is owned by the same assignee, international Business Machines Corporation and which is incorporated herein by reference as stated.

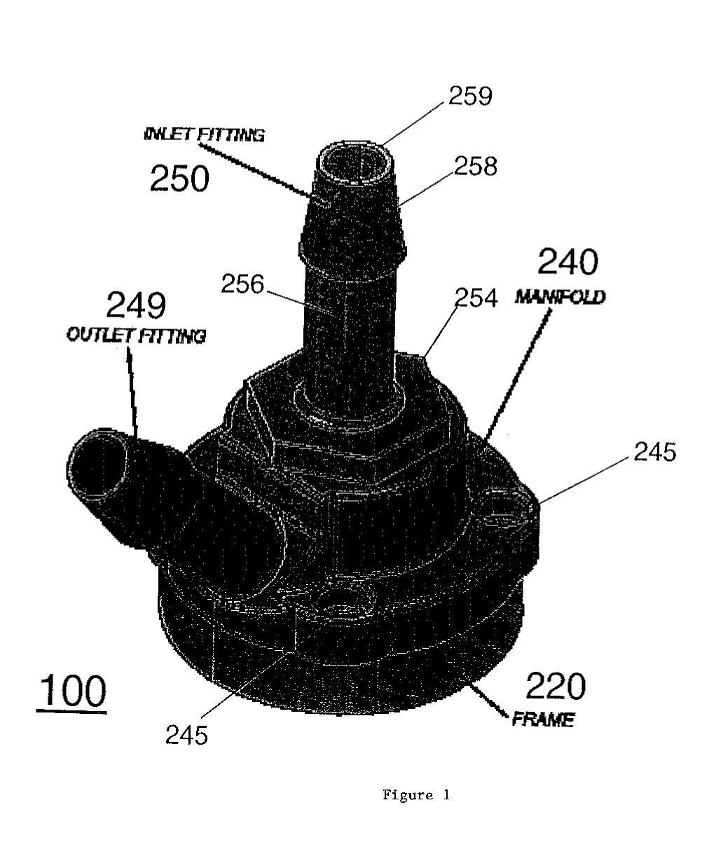

FIG. 1 provides for one embodiment of the present invention. In the embodiment illustrated in FIG. 1, a direct liquid jet impingement module 100 for high heat flux electronics packages is depicted. Liquid jet impingement cooling methods are a preferred method of resolving heat dissipation issues because of the many advantages that this method provides. The high heat transfer coefficients especially make liquid jet impingement an attractive cooling option where high heat fluxes are the norm. For example, long-term semiconductor performance may be adversely affected by high temperatures if not sufficiently mitigated. Liquid jet impingement cooling systems, such as the one provided in FIG. 1, can greatly remove the heat from these components and maintain them at a lower temperature.

One reason for this is that impinging liquid jets directly over electronics packages, have been demonstrated to be an effective means of providing high heat and mass transfer rates. When a liquid jet strikes a surface, thin hydrodynamic and thermal boundary layers are formed in the region located directly beneath the jet. Thereafter, the flow is forced to accelerate in a direction parallel to the cooled surface, hereinafter referenced as the target surface. This accelerated flow is directed in what is termed as the wall jet or parallel flow zone.

The thickness of the hydrodynamic and thermal boundary layers in the stagnation region may be of the order of tens of micrometers. Because of this, very high heat transfer coefficients exist in the stagnation zone directly under the jet. Transport coefficients characteristic of parallel flow prevail in the wall jet region.

High heat transfer coefficients make liquid jet impingement an attractive cooling option for some industrial applications, especially those that include the thermal treatment of metals, cooling of internal combustion engines, and as is the case in the present application, thermal control of high-heat-dissipation electronic devices. Referring back to FIG. 1, the benefits of liquid impingement as enumerated can be incorporated in the direct liquid impingement module 100 of FIG. 1.

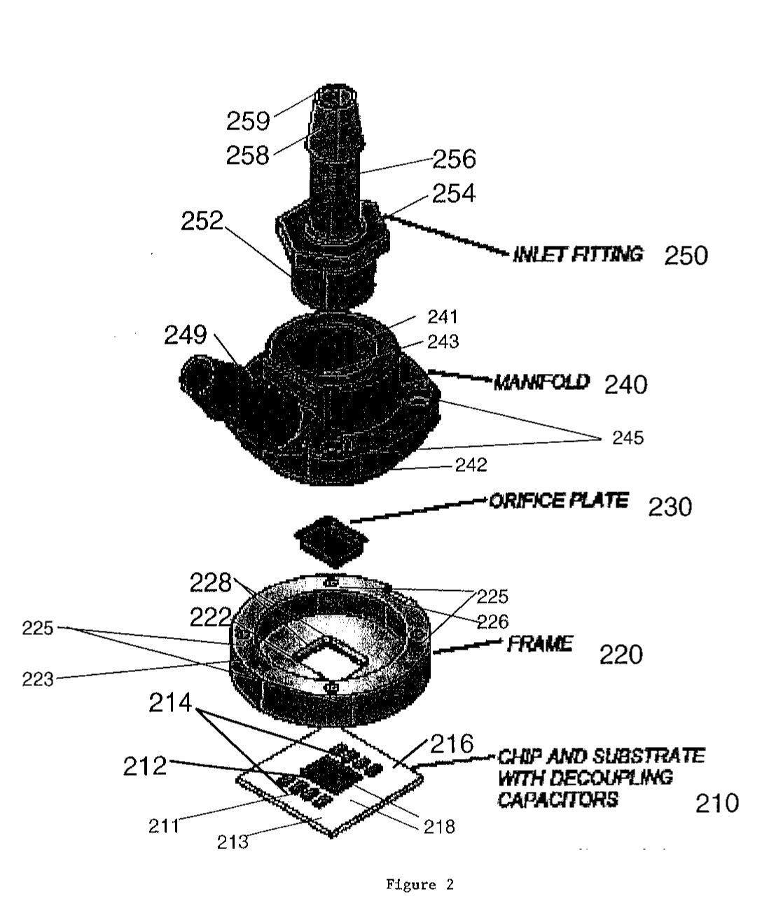

FIG. 1 provides for an isothermic view of the direct liquid impingement module 100 as per one embodiment of the present invention. The direct liquid impingement module of FIG. 1 is comprised of several components as will be presently discussed. FIG. 2 provides for an exploded view of the components that comprise the embodiment illustrated in conjunction with FIG. 1 and can be used in conjunction with the assembled view as provided by FIG. 1 to aid understanding.

As illustrated particularly in FIG. 2, the direct liquid impingement module 100 of FIG. 1, is to be placed over the to-be-cooled electronics package 210. Electronics package 210 in the exemplary embodiment of FIG. 2 is illustrated to be comprised of a single chip module (SCM) package 212 having one or more discrete devices 214, such as but not limited to an integrated circuit chip, one or more capacitors, resistors, and or memory devices or other discrete electronics devices.

In the example as illustrated in conjunction with FIG. 2, the electronics package 210 is shown to include at least one integrated circuit chip 212. Other discrete device(s), such as capacitors 214, are also illustrated. Both the integrated circuit chip 212 and the discrete device(s) 214, in this example, are secured to a component carrier 216. Integrated circuit chip 212 can be one with a high power density level that can generate a large amount of heat from a small surface area. For example, integrated circuit chip 212 can have a power density level that could exceed 500 W/cm².

The integrated circuit chip 212 and discrete devices (capacitors) 214 have bottom surfaces 211 and 213, respectively, and top surfaces (not visible in the viewed depiction). The top surfaces of the integrated circuit chip and the discrete device(s) 214 can be secured to the component carrier's 216 surface or other such similar surfaces by a variety of ways known to those skilled in the art. In the example provided by FIG. 2, the integrated circuit chip 212 and other discrete devices 214 are secured to the component carrier 216 by one or more solder connections (not illustrated) such that the integrated circuit chip 212 and discrete device(s) 214 are in electrical communication with one another. Solder connections between the component carrier 216 and the integrated circuit chip(s) 212 and discrete device(s) 214 can also be encapsulated, for example with epoxy, to reduce stress on solder connections due to thermal expansion mismatch between integrated circuit chip 212 and component carrier 216.

In the embodiment of FIG. 2, integrated circuit chip 212 has a generally polygonal shape defining a plurality of sides 218 which join the bottom surface 211 to the top surface (not illustrated but discussed). In the illustrated embodiment, integrated circuit chip 212 is shown to have a rectangular shape but other shapes, including non-polygons can be used if selectively desired.

A frame 220 is also provided as depicted in FIG. 2, fabricated in a manner as will be discussed later in greater details. Frame 220, preferably has an annular shape as depicted in FIG. 2. The annular shape of frame 220 is to enable its easy incorporation into the module 100 and its easy attachment to other components used in module 100.

Frame 220 has a thickness illustrated and referenced by numerals 223. In a preferred embodiment as shown, the frame 220 provides adequate surface area for a vertical annular (o-ring) seal such that the seal can properly fastens the manifold 240 to the frame 220. It should also be noted, that the annular shape of the seal/frame is not a requirement and is only provided for process flexibility and facility of later assembly with commonly available components. Frame shape, therefore, can be selectively altered to suit other needs.

Frame 220, also comprises of an opening or an opening 222. In the preferred embodiment of FIG. 2, the opening 222 is centrally located. In a preferred embodiment, a matching seal (not illustrated here) is provided to and formed around the integrated circuit chip 210 area to prevent leakage of unwanted liquid coolants to other adjacent areas. In a preferred embodiment, the matching seal member is annular in shape and located such that coolant fluid cannot reach chip C4s or other surfaces, such as substrate top surface metallurgy, causing electrical malfunctions. The particulars of the sealing member is provided in the related application enumerated above that is herein incorporated and will not be discussed in detail here. In such a case, however, the frame's opening or an opening 222 is connectable to the component carrier 216 so that the annular area is defined between the opening 222 and the electronic components (212/214).

It should be noted that the placement and shape of the opening 222 can be altered however based on the shape of the frame 220 itself, and other such similar factors such as the placement of the entire direct liquid jet impingement module 100. In either of these embodiments, regardless of shape and position of the opening 222, the enumerated matching sealing member can be used to provide liquid impingement only on the desired component such as the integrated circuit chip 212. In all such cases, the sealing member and the frame in conjunction with one another will be designed to prevent coolant fluid to contact the capacitors 214 or more importantly I/O connectors when such is placed on the component carrier 216.

The opening 222 is to be aligned with the integrated circuit chip 212 to provide direct liquid impingement cooling once the direct liquid jet impingement module 100 of the present invention is assembled as in FIG. 1. In a preferred embodiment, the opening 222 is formed as to create a secure fit over the integrated circuit chip 212 once the sealing member in place. In such an embodiment, as discussed, the frame and the sealing member can be used in conjunction to provide a liquid coolant sealed environment. In such a case, the shape of the opening 222 is identical to that of the integrated circuit chip 212 with the perimeter of the opening 222 being slightly larger than that of the integrated circuit chip 212 (with sides 228 of the orifice being slightly longer than that of the integrated circuit chip sides 218). In such a case, once the frame is placed over the integrated circuit chip 212, the liquid impingement is focused and directed towards the top surface 211 of the integrated circuit chip 212 alone.

In alternate embodiments, however, it is possible to form a larger opening 222, with appropriate sealing members, which may have a larger opening or include a different topology to include a larger area of the component carrier 216, if selectively desired. It is even conceivable to have an opening 222 and appropriate sealing members that can accommodate the entire component carrier 216 if desired.

Alternatively, it is possible to have a plurality of orifices, only one of which is illustrated in FIG. 2 as discussed. In such embodiments where the frame 220 houses multiple orifices, each orifice can be sized and shaped differently if desired, not just to fit over one integrated circuit chip 212, but also to be securely fit over one or more components, such as other integrated chips provided on the component carrier 216. In this case more than one sealing member accordingly will be used and retrofitted over the plurality of matching orifices, in order to prevent fluid leakage to unwanted adjacent areas.

The frame 220 can be secured to the manifold 240 or other elements in the computing environment in a variety of ways known to those skilled in the art. It should be noted that in preferred embodiments, the frame 220 is attached to the substrate to establish the (annular) seal. The subassembly can then be secured to the manifold 240. Thereafter, the inlet fitting to the manifold can be shaped. For example a single pipe can be molded to act both as the inlet and outlet fitting. Furthermore, in the example provided by illustration of FIG. 2, a plurality of attachment components 225 and 226 are illustrated. The attachment components are fabricated to align with counterpart alignment components in the manifold 240 or other such surfaces as will be discussed. In the example depicted by the illustration of FIG. 2, the alignment components 225 are a series of circular openings or holes, through which a screw or pin can be driven to ensure proper attachment and securing of the frame to other components. Alternatively, the fastening means can be replaced by mechanical means such as a clamp in order to hold the parts more securely together. Alignment component 226 is different in shape, having an elongated surface, that can be securely fit into an alignment counterpart to attach the frame 220 securely to manifold 240. Use of epoxy or other securing means can also be used to further ensure proper attachment of the frame 220 to the manifold 240 or other such components in the computing environment.

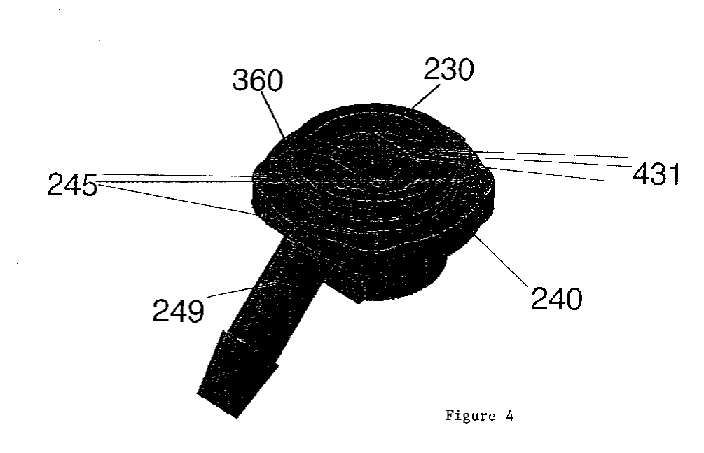

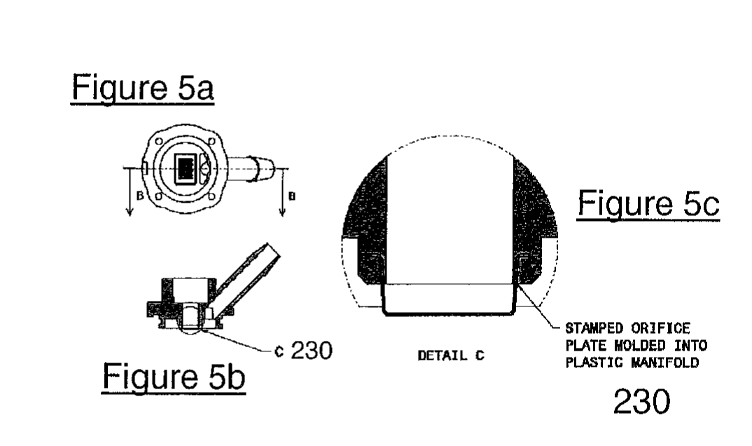

The manifold 240 provides for a jet orifice plate illustrated separately and referenced as 230. The jet orifice plate 230 is provided to better control impingement of the fluid into the backside of the die. Consequently, the jet orifice plate 230 is aligned with the opening 222 once assembled. In a preferred embodiment, the jet orifice plate 230 is molded into the manifold 240, even though, shown separately for ease of understanding. A detailed cross sectional view of the orifice plate 230 after being molded into the manifold 240 is provided in FIGS. 4 and 5a though 5c.

In the preferred embodiment provided in FIG. 4, a bottom-up cross sectional illustration of the manifold 240 providing more details of the molded orifice plate 230. In this figure, the orifice plate 230 is illustrated having a plurality of orifices 431 (appearing as dots in the figure) to provide more control the velocity (accelerate) of impinging fluid(s).

Similarly, FIG. 5a provides for a cross sectional view of the manifold 240 secured to the frame 220 along lines B-B. FIG. 5b provides for a cross sectional view of the manifold 240 and FIG. 5c provides for a detail illustration of area C as previously illustrated in FIG. 5b. In fact, FIG. 5c is a magnified view of FIG. 5b along the line c.

It should be noted, that a variety of techniques known to those skilled in the art can be used to form jet orifice plate 230 that is molded in the manifold 240. In a preferred embodiment, the orifice plate 230 is formed by a combination of etching techniques, used to form the jet orifices, and a stamping operation to produce the cross section seen in FIG. 5c.

The manifold 240 comprises an opening 241 which is complementarily shaped with the inlet fitting. Once the manifold 240 is disposed over the frame 220, the manifold opening 240 and the frame orifice 220 will be aligned. As discussed the jet orifice plate 230 is also to be housed in the manifold 240, inside this opening 241 such that once the manifold 240 is disposed over the frame 220 as discussed, the jet orifice plate 230 will be aligned and placed directly over the frame opening 222.

The manifold opening 241 comprises a plenum 242/243 for providing direct liquid impingement on the integrated circuit chip 212. The spray area comprises of two portions. The first portion illustrated and referenced as 243 is to accommodate inlet fitting into the manifold 240. The coolant will be provided through the inlet fitting 250. The liquid coolant will then traverse the manifold through the plenum 242/243 via the orifice plate on the integrated chip 212.

The manifold 240 also comprises of an outlet fitting 249 that can be molded during the same process step as the manifold itself. The outlet fitting 249 can be integral to the manifold 240 or it can be a separate entity that is secured to the manifold 240 though attachments as will be appreciated by those skilled in the art. In a preferred embodiment of the present invention, the manifold can be formed from plastics and plastic component and molded to the desired shape as illustrated in the figures.

As discussed earlier, matching attachment components referenced as 245 can also be provided on the manifold 240. These attachment components 245 will be aligned with the ones provided on the frame (previously discussed as referenced numerals 225) to ensure proper attachment and securing of the manifold 240 to the frame 220. A variety of techniques known to those skilled in the art, as was briefly discussed before, can be used to accommodate the attachment. For example a combination of screws and pins used in conjunction with epoxy can be used in one such embodiment.

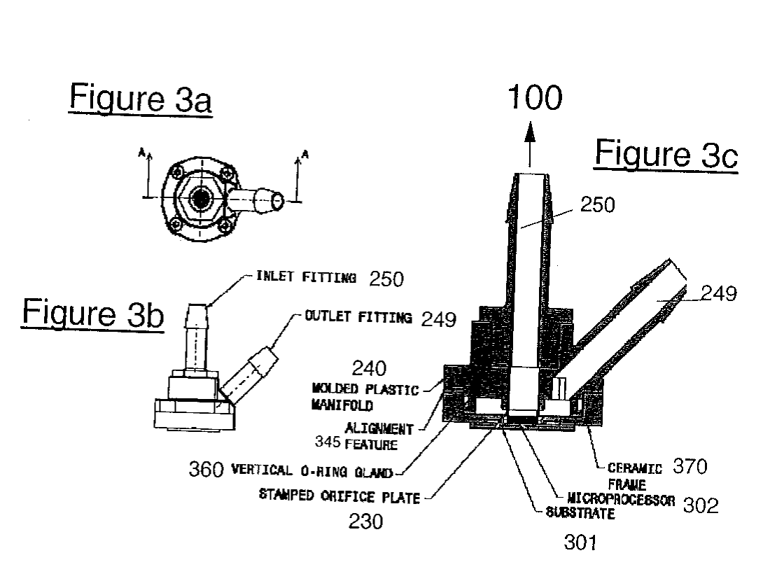

In addition, in a preferred embodiment, the manifold 240 is fluidly sealed to the frame by providing another sealing member (not viewable in FIG. 1 or 2 but illustrated in FIGS. 3 and 4). In a preferred embodiment, for example, this other sealing member will be an o-ring seal provided on the vertical surface of the frame 220. The o-ring seal or gland is not viewable in the illustration of FIG. 1 or 2, but can be viewed in the cross sectional illustration of FIG. 3c. The o-ring gland in FIG. 3c is referenced as 360.

The manifold 240 as illustrated is shaped to receive inlet fitting 250 (to provide fluid coolant flow ultimately on the to-be-cooled components 212) and outlet fitting 249 to remove dissipated heat in all forms (such as vapor) away from the now cooled component (212) after jet impingement process has been completed. The inlet and outlet fitting 250 and 249 will also be ultimately attached to complementary components, such as coolant supply unit for example and not illustrated here, to enable the flow of coolants into the module and the removal of dissipated heat respectively.

As illustrated, the inlet fitting 250, is disposed inside the manifold plenum 242/243, formed to accept the inlet fitting 250 as previously discussed. In a preferred embodiment, where an annular design is used for the spray area 242/243 of the manifold 240, the insertion area 252 is tubular in shape and sized to provide a secure fit with the spray area 242/243.

Other appropriately placed sealing members can be used in conjunction with the inlet fitting 250 (or alternatively outlet fitting 249) to prevent fluid leaking to unwanted areas of the computing environment.

Once the components shown specifically are assembled as discussed, the resultant direct liquid jet impingement module 100 of FIG. 1 will ensue. FIG. 3a through 3c also provide for alternate views of the assembled direct liquid jet impingement module 100 previously illustrated in FIG. 1. FIGS. 3a and 3b provide different views (top down and side views respectively) cross sectional schematic illustrations of the direct liquid jet impingement (DLJI) module 100.

FIG. 3c provides greater detail of the DLJI module 100 cut across lines AA of FIG. 3a. Some features are provided in FIG. 3c that were not viewable possible in other embodiment as previously discussed, such as vertical o-ring gland 360. At the same time, FIG. 3c provides some a preferred embodiment incorporating certain features not previously discussed. For example, as illustrated, the frame 220, in one embodiment is a ceramic frame, referenced here as 370 and housing alignment matching 345 are provided. Similarly, module 100 is disposed over a substrate 301 including a microprocessor 302 is placed for direct liquid impingement cooling as shown.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A direct liquid jet impingement module used in cooling of electronic components housed in an electronic package comprising: a frame having a frame opening to be placed over to-be-cooled component; a manifold disposed over said frame and having a manifold opening to be aligned with said frame opening; said manifold further shaped to receive an inlet fitting for supplying coolants and having an outlet fitting for removal of dissipated heat; and a jet orifice plate provided in said manifold for and aligned with said frame opening for directing fluid coolant flow over to-be-cooled components.

2. The module of claim 1, wherein said frame and said manifold are secured to one another.

3. The module of claim 2, wherein said alignment features are complementary such that they align to form one possible angular orientation.

4. The module of claim 2, wherein said frame and said manifold each have attachment components for securing said frame to said manifold.

5. The module of claim 2, wherein said jet orifice plate is molded into said manifold.

6. The module of claim 2 wherein a sealing member is provided between said frame and said manifold.

7. The module of claim 8, wherein said sealing member is an o-ring seal.

8. The module of claim 9, wherein said sealing member is provided on vertical frame of said frame.

9. The module of claim 1, wherein said opening is shaped to fit to-be-cooled component.

10. The module of claim 1, wherein one or more annular seals are provided between said orifice and to-be-cooled component.

11. The module of claim 1, wherein said frame is annular in shape.

12. The module of claim 1, wherein said manifold is fabricated of plastic or plastic components.

13. The module of claim 1, wherein said separate frame is fabricated out of ceramic.

14. The module of claim 1, wherein said separate frame is fabricated out of copper.

15. The module of claim 1, wherein said inlet fitting further comprises a manifold plenum having an insertion area made to fit into said manifold, a cover used to stop progress of insertion area into said manifold and an upper inlet area for receiving fluid coolants.

16. The module of claim 1, wherein said upper inlet area of said inlet fitting include a receiving fluid head.

17. The module of claim 1, wherein said module is attached to a semiconductor substrate housing said to be cooled electronic components.

18. A method of providing direct liquid jet impingement used in cooling of electronic components housed in an electronic package comprising: providing jet impingement cooling by directing coolants through an orifice of a frame disposed over to-be-cooled electronic component, aligning said frame orifice with an opening of a manifold shaped to receive and inlet fitting to provide coolants; controlling flow of said fluid coolants thorough a jet orifice plate disposed over said frame's orifice but housed in said manifold; and removing dissipated heat through an outlet fitting on said manifold.

19. The method of claim 1, further comprising the step of securing said frame to a semiconductor substrate housing said to be cooled electronic components.

20. A method of assembling a liquid jet impingement module comprising: connecting a semiconductor substrate housing to be cooled electronic components to a frame through an opening on said frame such as to enable impingement cooling; aligning said frame orifice with an opening of a manifold attached to said frame and substrate assembly; said manifold shaped to receive an inlet fitting to provide coolants; and outlet fitting for removal of dissipated heat.
